(19) United States
(12) Patent Application Publication
(10) Pub. No.: US 2026/0040683 A1
(43) Pub. Date: Feb. 5, 2026

(54) SEMICONDUCTOR DEVICE

(71) Applicant: Socionext Inc., Kanagawa (JP)

(72) Inventors: Hirotaka TAKENO, Yokohama (JP); Wenzhen WANG, Yokohama (JP); Atsushi OKAMOTO, Yokohama (JP)

(21) Appl. No.: 19/352,535

(22) Filed: Oct. 8, 2025

Related U.S. Application Data
(63) Continuation of application No. PCT/JP2023/014838, filed on Apr. 12, 2023.

(51) Int. Cl. H10D 84/90; H10D 89/10

(52) U.S. Cl. CPC H10D 84/981; H10D 84/961; H10D 89/10

(57) ABSTRACT

A semiconductor device includes a substrate in which a via is formed, first through fourth power supply lines each formed below the substrate and extending in a first direction, and a power switch circuit including a first transistor formed above the substrate. The power switch circuit overlaps the second power supply line in a plan view and does not overlap the fourth power supply line in a plan view. The first transistor is arranged at a position overlapping the first power supply line in a plan view, and a source of the first transistor is coupled to a via coupled the first power supply line. The second and fourth power supply lines are coupled to each other via an interconnect extending in a second direction.

### CROSS-REFERENCE TO RELATED APPLICATIONS

This application is a continuation application of International Application No. PCT/JP2023/014838 filed on Apr. 12, 2023, and designated the U.S., the entire contents of which are incorporated herein by reference.

### BACKGROUND

### 1. Technical Field

The present invention relates to a semiconductor device.

### 2. Description of Related Art

It is known to provide a power switch circuit for switching a power source between supplying and shutting off power to a transistor in a semiconductor device such as a standard cell. A backside power delivery network (BSPDN) technology in which a power supply line is provided on a back surface of a semiconductor substrate and power is supplied to a transistor provided on a front surface of the semiconductor substrate via a through silicon via (TSV). A technology of directly coupling vias to a source and a drain of a transistor provided on the front surface of a semiconductor substrate from the back surface of the semiconductor substrate is known.
Patent Document 1: U.S. Patent Application Publication No. 2022/0344263
Patent Document 2: U.S. Patent Application Publication No. 2022/0208757
Patent Document 3: U.S. Patent Application Publication No. 2021/0272903
Patent Document 4: U.S. Patent Application Publication No. 2019/0305773
Patent Document 5: International Publication No. WO 2020/065916
Patent Document 6: International Publication No. WO 2022/066797
Patent Document 7: U.S. Pat. No. 11,552,069

### SUMMARY

According to one aspect of the present disclosure, a semiconductor device, includes a substrate in which a first via is formed, a first power supply line supplied with a first potential, a second power supply line supplied with a second potential, a third power supply line supplied with a third potential, a fourth power supply line supplied with the second potential, the first power supply line, the second power supply line, the third power supply line, and the fourth power supply line being formed below the substrate, and a power switch circuit including a first transistor formed above the substrate and electrically coupled between the first power supply line and the second power supply line. The first power supply line, the second power supply line, the third power supply line, and the fourth power supply line each continuously extend in a first direction in a plan view. The first transistor includes a first source and a first drain. The first transistor is arranged at a position overlapping the first power supply line in a plan view. The first source is coupled to the first via coupled to the first power supply line. The first power supply line, the second power supply line, the third power supply line, and the fourth power supply line are arranged side by side in a second direction different from the first direction in a plan view. The second power supply line and the fourth power supply line are electrically coupled to each other via an interconnect extending in the second direction. The power switch circuit is arranged at a position overlapping the second power supply line and not overlapping the fourth power supply line in a plan view.

### BRIEF DESCRIPTION OF THE DRAWINGS

FIG. 1 is a plan view illustrating an example of a layout in a semiconductor device according to an embodiment;

FIG. 2 is a cross-sectional view illustrating an example of a cross-sectional structure of the semiconductor device of FIG. 1;

FIG. 3 is a circuit diagram illustrating an example of a circuit arranged in a standard cell block of FIG. 1;

FIG. 4 is a plan view illustrating a positional relationship between power supply lines, virtual power supply lines, ground lines, and vias, all of which are arranged in the back surface side of a semiconductor substrate at respective positions overlapping the standard cell block of FIG. 3, and power switch circuits in a plan view;

FIG. 5 is a plan view illustrating an example of a layout in the power switch circuit illustrated in FIGS. 3 and 4;

FIG. 6 is a plan view illustrating an example of a layout in a wider area than that of FIG. 5;

FIG. 7 is a cross-sectional view illustrating an example of a cross section taken along line X1-X2 in FIG. 5;

FIG. 8 is a cross-sectional view illustrating another example of a cross section taken along line X1-X2 in FIG. 5;

FIG. 9 is a cross-sectional view illustrating yet another example of a cross section taken along line X1-X2 in FIG. 5;

FIG. 10 is a plan view illustrating a first modified example of a layout in the power switch circuit illustrated in FIG. 3;

FIG. 11 is a plan view illustrating a second modified example of a layout in the power switch circuit illustrated in FIG. 3;

FIG. 12 is a plan view illustrating a third modified example of a layout in the power switch circuit illustrated in FIG. 3;

FIG. 13 is a plan view illustrating a modified example of a layout illustrated in FIG. 4; and

FIG. 14 is a plan view illustrating an example of a layout in the power switch circuit and the control circuit illustrated in FIG. 13.

### DETAILED DESCRIPTION

Specific studies have not been conducted regarding how to arrange and couple interconnects and vias, etc. in the case where a power supply line formed below a semiconductor substrate and the source and drain of a power supply switch circuit formed above the semiconductor substrate are directly coupled by the vias formed in the semiconductor substrate. For example, how a virtual power supply line, which is not adjacent to a power supply line and is generated as a result of reducing the arrangement frequency of the power supply lines below the semiconductor substrate, is coupled to a power switch circuit, which is formed at a position overlapping the power supply line in a plan view, has not been considered.

According to the disclosed technique, a fourth power supply line arranged at a position away from power switch circuits by reducing the arrangement frequency of first power supply lines below a substrate can be coupled to the power switch circuits formed at positions overlapping the first power supply lines in a plan view.

Hereinafter, embodiments will be described with reference to the drawings. In the descriptions hereinafter, a symbol indicating a signal is also used as a symbol indicating a signal line or a signal terminal. A symbol indicating a power supply potential is also used as a symbol indicating a power supply line or a power supply terminal to which the power supply potential is supplied.

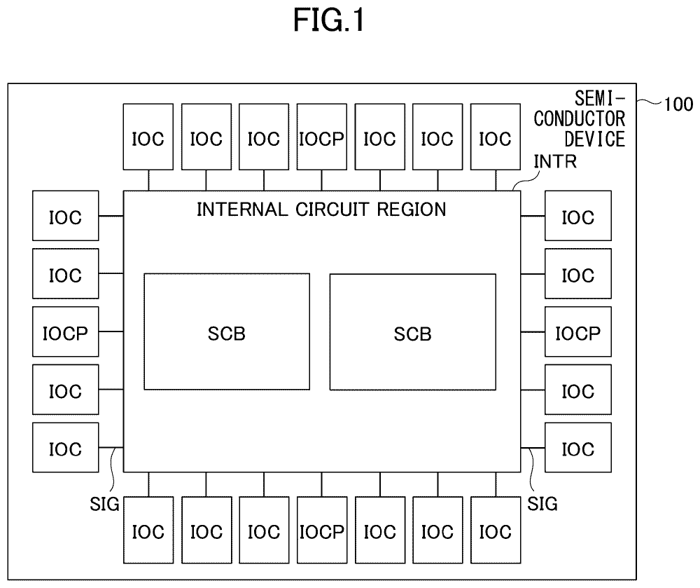

FIG. 1 illustrates an example of a layout in a semiconductor device according to an embodiment. For example, the semiconductor device 100 illustrated in FIG. 1 may be a system-on-a-chip (SoC), a single field-programmable gate array (FPGA), or the like.

The semiconductor device 100 includes a plurality of I/O cells IOC and IOCP and an internal circuit region INTR. The I/O cell IOC is an interface circuit for a signal SIG such as an input signal, an output signal, or an input/output signal. The I/O cell IOCP is an interface circuit for a power supply potential or a ground potential.

The I/O cells IOC and IOCP are coupled to the internal circuit region INTR. For example, the internal circuit region INTR includes one or more standard cell blocks SCB in which standard cells are provided. In the internal circuit region INTR, a logic circuit other than the standard cell may be mounted, or a memory may be mounted. A memory may be mounted in the standard cell block SCB. For example, a transistor mounted on the semiconductor device 100 may be a fin field effect transistor (FET), a nanosheet FET, or a complementary FET (CFET).

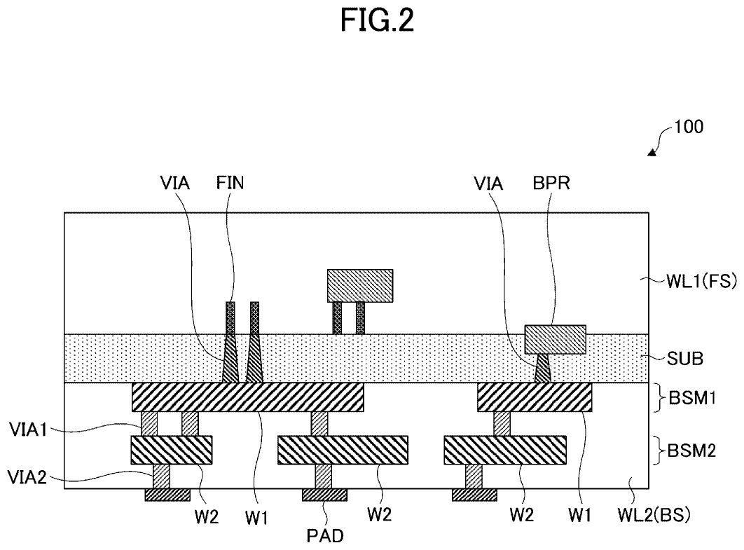

FIG. 2 illustrates an example of a cross-sectional structure of the semiconductor device 100 of FIG. 1. The semiconductor device 100 includes a substrate SUB, an interconnect layer WL1 formed on a front surface side FS of the substrate SUB, and an interconnect layer WL2 formed on a back surface side BS of the substrate SUB. The front surface side FS of the substrate SUB is an example of a side above the substrate SUB, and the back surface side BS of the substrate SUB is an example of a side below the substrate SUB. A fin FIN which is a part of a transistor is formed on the surface of the substrate SUB. The fin FIN has a source, a drain, and a channel. A pad PAD, which is an external coupling terminal, is formed on the surface (back surface) opposite to the surface on which the substrate SUB is provided in the interconnect layer WL2.

The interconnect layer WL2 includes a plurality of interconnect layers BSM1 and BSM2 (two layers in FIG. 2, and BSM is an abbreviation of “backside metal”). For example, the interconnect layers BSM1 and BSM2 are respectively formed with interconnects W1 and W2 that respectively supply a power source potential and a ground potential. The interconnects W1 and W2 are coupled to each other through a via VIA1. The interconnect W2 and the pad PAD are coupled to each other through a via VIA2.

The interconnect W1 is coupled to the source of the fin FIN via a through silicon via (TSV) formed in the substrate SUB. The TSV is an example of a first via or a second via. The interconnect W1 may be coupled to a buried power rail (BPR) buried in the substrate SUB via the TSV.

A transistor formed on the substrate SUB is not limited to a fin FET using a fin, and may be, for example, a planar MOSFET, a nanosheet FET, or a complementary FET (CFET). In the planar MOSFET and the nanosheet FET, the via TSV that supplies a power supply potential or a ground potential is coupled to the source of the transistor. In the case of the CFET, the via TSV that supplies a power supply potential or a ground potential may be coupled to the source located closest to the substrate SUB.

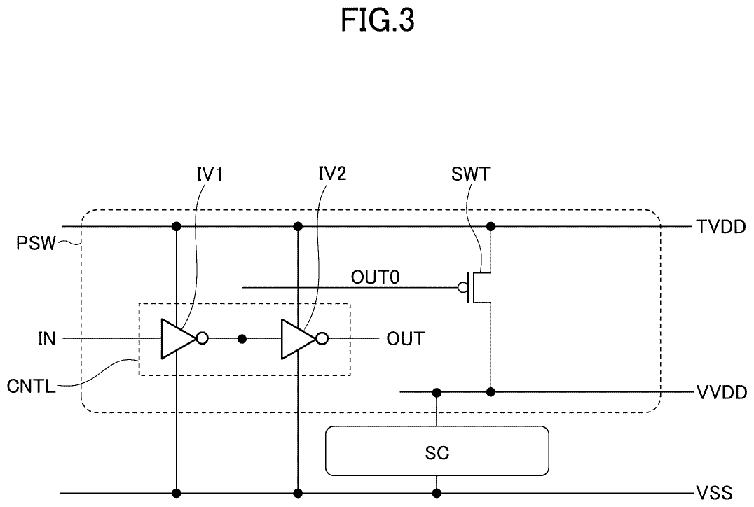

FIG. 3 illustrates an example of a circuit arranged in the standard cell block SCB of FIG. 1. The standard cell block SCB includes a power switch circuit PSW and a standard cell SC. The standard cell SC is coupled to a virtual power supply line VVDD and a ground line VSS, and operates in response to a supply of a virtual power supply potential VVDD from the virtual power supply line VVDD.

The power switch circuit PSW includes a control circuit CNTL and a switch transistor SWT. The control circuit CNTL is a buffer circuit having inverters IV1 and IV2 coupled in series between an input signal line IN and an output signal line OUT. The inverters IV1 and IV2 are coupled to a power supply line TVDD and the ground line VSS to operate. The inverter IV1 inverts the logic of an input signal IN and outputs an inverted signal as an output signal OUT0. The inverter IV2 inverts the logic of the output signal OUT0 that is output from the inverter IV1, and outputs an inverted signal as an output signal OUT.

The power supply line TVDD is an example of a first power supply line, and the power supply potential TVDD is an example of a first potential. The virtual power supply line VVDD is an example of a second power supply line, and the virtual power supply potential VVDD is an example of a second potential. The ground line VSS is an example of a third power supply line, and the ground potential VSS is an example of a third potential.

The switch transistor SWT is a PMOS transistor having a source coupled to the power supply line TVDD and a drain coupled to the virtual power supply line VVDD, and operates in response to a voltage of the output signal OUT0 that is output from the control circuit CNTL as a gate potential. While the switch transistor SWT is on, the power supply line TVDD and the virtual power supply line VVDD are electrically coupled to each other, and a power supply potential TVDD is supplied to the standard cell SC via the virtual power supply line VVDD. While the switch transistor SWT is off, an electrical coupling between the power supply line TVDD and the virtual power supply line VVDD is shut off, and the virtual power supply line VVDD is set to a floating state. Instead of the output of the inverter IV1, the input IN of the inverter IV1 or the output OUT of the inverter IV2 may be coupled to the gate of the switch transistor SWT. This is the same in other embodiments.

The control circuit CNTL may be arranged in a region different from the region where the power switch circuit PSW is arranged. The output signal OUT may be supplied to the input terminal IN of another power switch circuit PSW. The switch transistor SWT is an example of a first transistor formed above the substrate SUB and electrically coupled between the power supply line TVDD and the virtual power supply line VVDD.

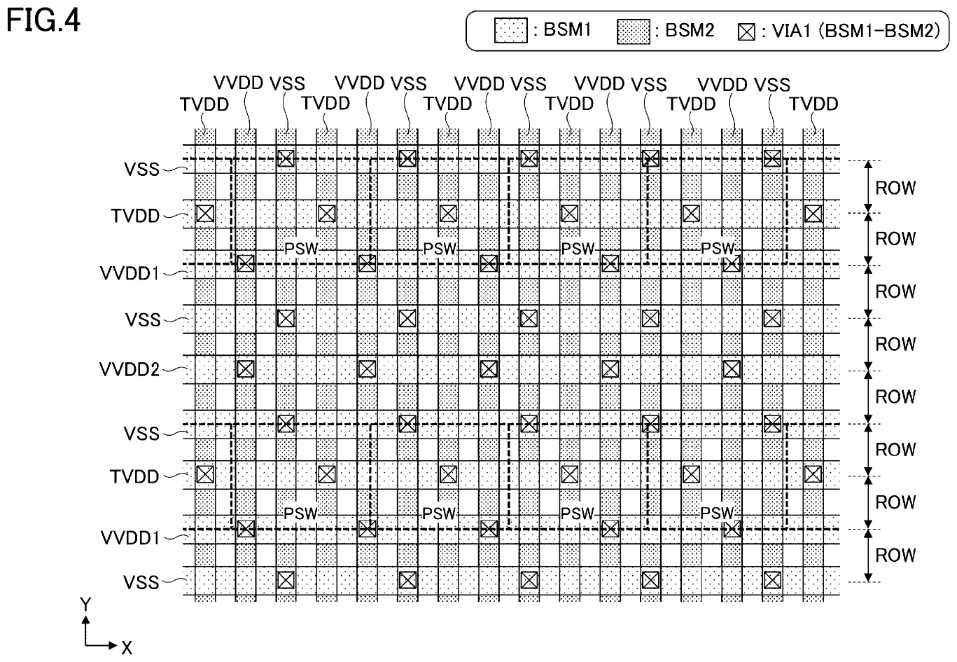

FIG. 4 is a plan view illustrating a positional relationship between the power supply lines TVDD, the virtual power supply lines VVDD, the ground lines VSS, and the vias VIA1, all of which are arranged in the back surface side BS of the semiconductor substrate SUB at respective positions overlapping the standard cell block SCB of FIG. 3, and the power switch circuits PSW in a plan view. Each interconnect of the interconnect layer BSM1 extends in an X direction without interruption, and each interconnect of the interconnect layer BSM2 extends in a Y direction, which is a second direction differing from the X direction. The X direction is an example of a first direction. The symbol “ROW” shown in FIG. 4 indicates a width of the standard cell SC in the Y direction in the interconnect layer BSM1.

In the interconnect layer BSM1, the ground lines VSS, the power supply lines TVDD, the virtual power supply lines VVDD1, the ground lines VSS, and the virtual power supply lines VVDD2 are arranged side by side in the Y direction. The virtual power supply line VVDD1 overlaps the power switching circuit PSW in a plan view, whereas the virtual power supply line VVDD2 does not overlap the power switching circuit PSW in a plan view. The virtual power supply line VVDD1 is an example of a second power supply line, and the virtual power supply line VVDD2 is an example of a fourth power supply line. In the case where the virtual power supply lines VVDD1 and VVDD2 are described without distinction, they are also referred to as a “virtual power supply line VVDD”.

The arrangement frequency of the power supply lines TVDD in the interconnect layer BSM1 is lower than the arrangement frequency of the virtual power supply lines VVDD and the arrangement frequency of the ground lines VSS. By reducing the arrangement frequency of the power supply lines TVDD, the arrangement frequency of the virtual power supply lines VVDD and the ground lines VSS can be relatively increased, and the interconnect resistance of the virtual power supply lines VVDD and the ground lines VSS can be relatively decreased.

In the interconnect layer BSM2, the power supply line TVDD, the virtual power supply line VVDD, and the ground line VSS are arranged in a repeated pattern in this order. The power switch circuits PSW indicated by the broken lines are arranged along the X direction, with the position of the power supply line TVDD of the interconnect layer BSM1 centered along the Y direction. The standard cells SC are arranged in a region where the power switch circuits PSW are not arranged. By arranging the power switch circuits PSW in a concentrated manner along the interconnect region of the power supply lines TVDD in the interconnect layer BSM1, the arrangement frequency of the power supply lines TVDD in the interconnect layer BSM1 can be reduced.

The virtual power supply lines VVDD of the interconnect layers BSM1 and BSM2 are coupled to each other through the vias VIA arranged at the intersections. The power supply lines TVDD of the interconnect layers BSM1 and BSM2 are coupled to each other through the vias VIA1 arranged at the intersections. The ground lines VSS of the interconnect layers BSM1 and BSM2 are coupled to each other through the vias VIA1 arranged at the intersections.

Although not particularly limited, the arrangement density (arrangement interval in the X direction) of the power switch circuits PSW may be set to be lower than that in FIG. 4.

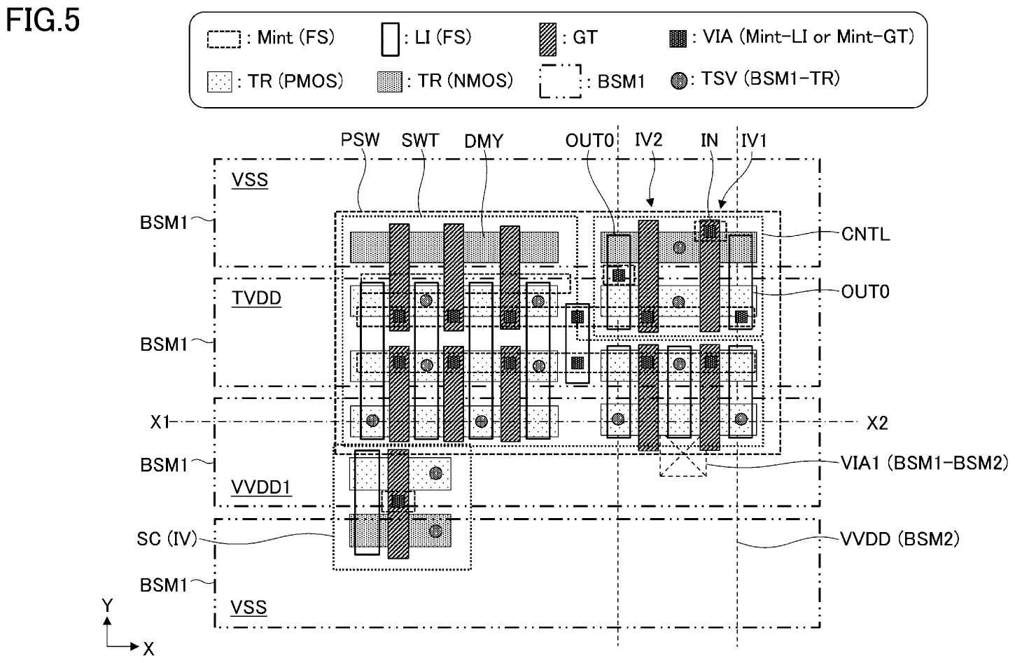

FIG. 5 illustrates an example of a layout in the power switch circuit PSW illustrated in FIGS. 3 and 4. In the legend illustrated in FIG. 5 and the drawings thereafter, the symbol “Mint” denotes an interconnect formed in the metal interconnect layer Mint closest to the substrate SUB among the plurality of metal interconnect layers. The symbol “LI” denotes a local interconnect formed in an interconnect layer closer to the substrate SUB than the Mint layer. The interconnect LI can be directly coupled to a source and a drain of the transistor. The symbol “GT” denotes a gate of the transistor. The symbol “VIA” denotes a via that couples the Mint interconnect and the local interconnect LI or a via that couples the Mint interconnect and the gate interconnect GT.

The symbol “TR (PMOS)” denotes a transistor region (source, drain, and channel) of a PMOS transistor. The symbol “TR (NMOS)” denotes a transistor region (source, drain, and channel) of an NMOS transistor. For example, in the fin FET, a fin is formed in the region TR. In the nanosheet FET, a semiconductor layer is formed as a source and a drain in the region TR, and a nanosheet as a channel is formed between the source and the drain.

The power switch circuit PSW includes a switch transistor SWT and a control circuit CNTL (buffer circuit) arranged along the X direction in a plan view. For example, the power switch circuit PSW is designed as one cell. The switch transistor SWT is arranged at a position overlapping the ground lines VSS, the virtual power supply line VVDD and the power supply line TVDD of the interconnect layer BSM1 in a plan view.

In the switch transistor SWT, the source of the PMOS transistor overlapping the power supply line TVDD of the interconnect layer BSM1 in a plan view is directly coupled to the TSV coupled to the power supply line TVDD of the interconnect layer BSM1. The TSV directly coupled to the source of the PMOS transistor overlapping the power supply line TVDD of the interconnect layer BSM1 in a plan view is an example of a first via. In the switch transistor SWT, the source of the PMOS transistor that does not overlap the power supply line TVDD of the interconnect layer BSM1 in a plan view is coupled to, via the local interconnect LI, the source of the PMOS transistor coupled to the TSV of the power supply line TVDD. “Directly coupled” means that a conductor included in the TSV is in contact with a semiconductor layer including a source, a drain, or the like of each transistor, and also includes, for example, a case where the TSV includes a plurality of layers of conductors, a part of the plurality of layers of conductors being in contact with the semiconductor including the source or the drain of the transistor.

In the switch transistor SWT, the drain of the PMOS transistor that overlaps the virtual power supply line VVDD1 of the interconnect layer BSM1 in a plan view is directly coupled to the virtual power supply line VVDD1 of the interconnect layer BSM1 via the TSV. In the switch transistor SWT, the drain of the PMOS transistor that does not overlap the virtual power supply line VVDD1 of the interconnect layer BSM1 in a plan view is coupled to, via the local interconnect LI, the drain of the PMOS transistor coupled to the TSV of the virtual power supply line VVDD1.

In the switch transistor SWT, a dummy transistor DMY (NMOS) is arranged in a region overlapping the ground line VSS of the interconnect layer BSM1 in a plan view. The dummy transistor DMY need not be arranged at all.

The control circuit CNTL is arranged at a position overlapping the ground line VSS and the power supply line TVDD of the interconnect layer BSM1 in a plan view. The source of the PMOS transistor of the control circuit CNTL is directly coupled to the power supply line TVDD of the interconnect layer BSM1 via the TSV. The source of the NMOS transistor of the control circuit CNTL is directly coupled to the ground line VSS of the interconnect layer BSM1 via the TSV.

The source of the PMOS transistor of the inverter IV arranged in the standard cell SC is directly coupled to the virtual power supply line VVDD1 of the interconnect layer BSM1 via the TSV. The source of the NMOS transistor of the inverter IV arranged in the standard cell SC is directly coupled to the ground line VSS of the interconnect layer BSM1 via the TSV.

The control circuit CNTL (inverters IV1 and IV2) may be included in the power supply switch circuit PSW or arranged separately from the power supply switch circuit PSW. In this case, the power switch circuit PSW and the control circuit CNTL may be designed as different cells. Alternatively, a plurality of power switch circuits PSW may be controlled by one control circuit CNTL.

The virtual power supply line VVDD1 of the interconnect layer BSM1 is coupled to the virtual power supply line VVDD of the interconnect layer BSM2 through the via VIA1. In other words, the drain of the PMOS transistor coupled to the virtual power supply line VVDD1 of the interconnect layer BSM1 via the TSV is electrically coupled to, via the virtual power supply line VVDD of the interconnect layer BSM2, the virtual power supply line VVDD2 (FIG. 4) that does not overlap the power switching circuit PSW in a plan view. Although not illustrated, the power supply line TVDD and the ground line VSS in the interconnect layer BSM1 are also coupled to the corresponding power supply line TVDD and ground line VSS in the interconnect layer BSM2 as illustrated in FIG. 4.

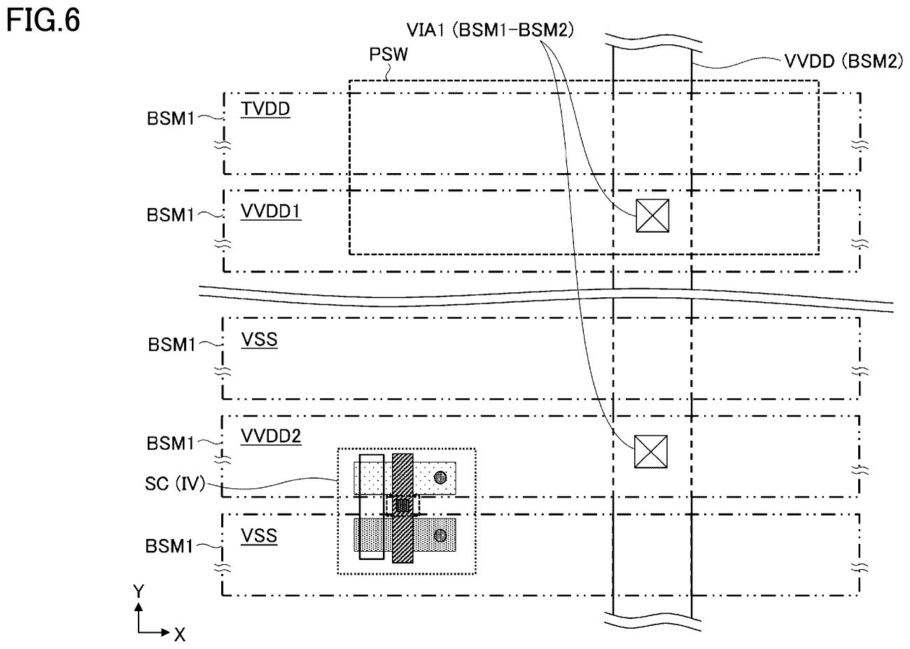

FIG. 6 illustrates an example of a layout in a wider area than that of FIG. 5. The power switch circuit PSW illustrated in FIG. 6 corresponds to the power switch circuit PSW in FIG. 5. The ground line VSS is arranged on each Y-direction side of the virtual power supply line VVDD2 of the interconnect layer BSM1 facing the standard cell SC (inverter IV) in a plan view. In other words, since the virtual power supply line VVDD2 is not formed at a position overlapping the power switching circuit PSW in a plan view, the virtual power potential VVDD generated by the power switching circuit PSW cannot be supplied to the standard cell SC only by an interconnect of the interconnect layer BSM1.

For this reason, in FIG. 6, the virtual power supply line VVDD1 of the interconnect layer BSM1 formed at a position overlapping the power switching circuit PSW in a plan view is coupled to the virtual power supply line VVDD2 through the via VIA1 and the virtual power supply line VVDD of the interconnect layer BSM2. This makes it possible to supply the virtual power supply potential VVDD generated by the power switch circuit PSW to the standard cell SC.

In this case, since the power supply lines TVDD of the interconnect layer BSM1 do not have to be arranged at positions overlapping the standard cells SC in a plan view, the arrangement frequency (the number of items being arranged) of the power supply lines TVDD of the interconnect layer BSM1 can be reduced. In other words, in a layout in which the arrangement frequency of the power supply lines TVDD in the interconnect layer BSM1 is reduced, the virtual power potential VVDD can be supplied from the power switching circuit PSW to the virtual power supply line VVDD2 that is not formed at a position overlapping the power switching circuit PSW in a plan view.

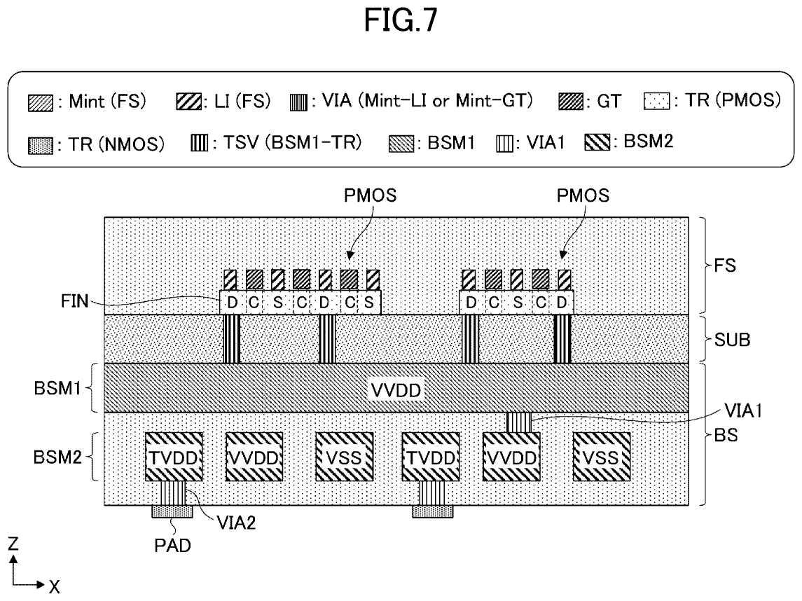

FIG. 7 illustrates an example of a cross section taken along line X1-X2 in FIG. 5. The virtual power supply line VVDD formed in the interconnect layer BSM1 on the back surface side BS is coupled to the P-type impurity region (the drain D of the PMOS transistor) of the fin FIN formed on the front surface side FS via the TSV formed in the substrate SUB.

In each fin FIN, a channel C is arranged between a source S and a drain D. A gate GT is arranged on the channel C via a gate insulating film (not illustrated). In FIG. 7, two interconnect layers BSM1 and BSM2 are arranged on the back surface side BS, but three or more interconnect layers BSM may be arranged thereon.

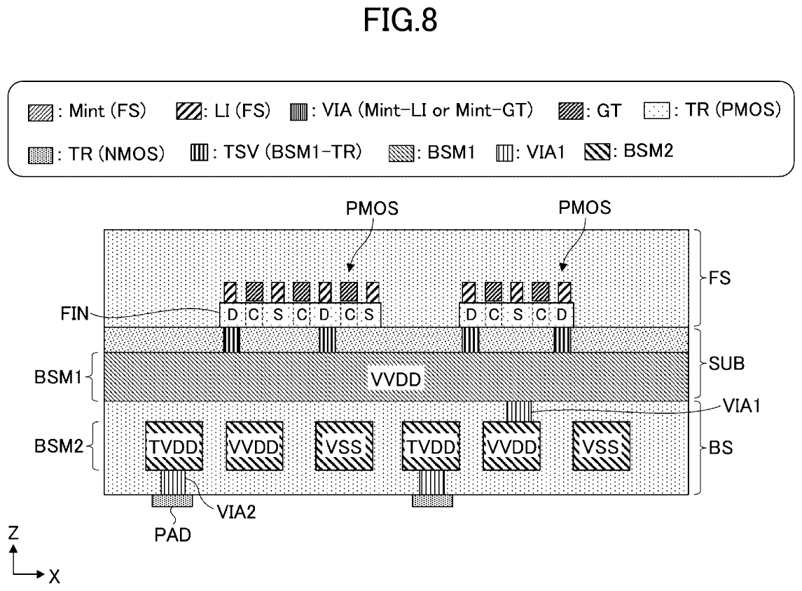

FIG. 8 illustrates another example of a cross section taken along line X1-X2 in FIG. 5. FIG. 8 is the same as the cross-sectional structure of FIG. 6 except that the interconnect layer BSM1 is formed on the back surface side BS of the substrate SUB. The interconnect layer BSM1 illustrated in FIG. 7 is different from the buried power rail BPR (FIG. 2) buried in the front surface side FS of the substrate SUB.

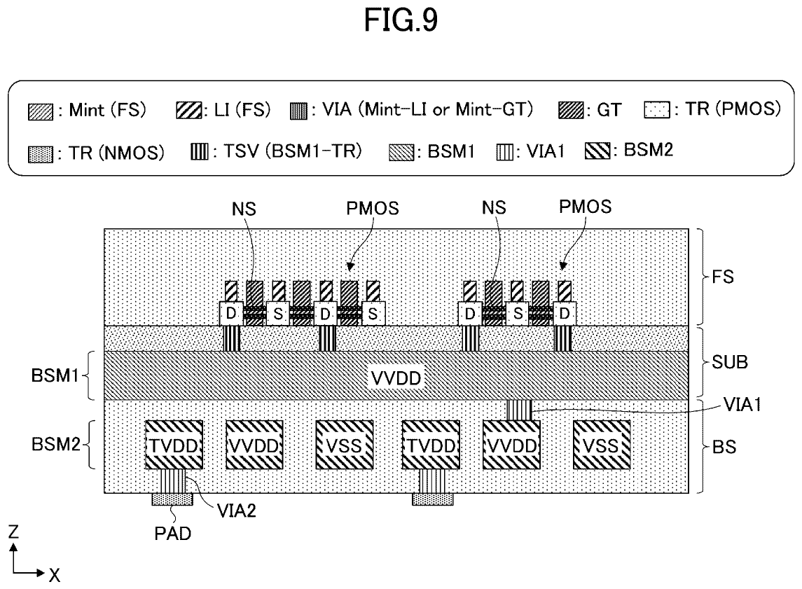

FIG. 9 illustrates yet another example of a cross section taken along line X1-X2 in FIG. 5. FIG. 9 is the same as the cross-sectional structure of FIG. 7 except that the transistor formed on the substrate SUB is a nanosheet FET. The nanosheet FET includes a semiconductor layer having a source S and a drain D, a nanosheet NS having a semiconductor material formed between the source S and the drain D, and a gate electrode GT formed with a gate insulating film (not illustrated) interposed between the gate electrode GT and the nanosheet NS. This nanosheet FET may be arranged on the front surface side FS, instead of the fin FET illustrated in FIG. 8.

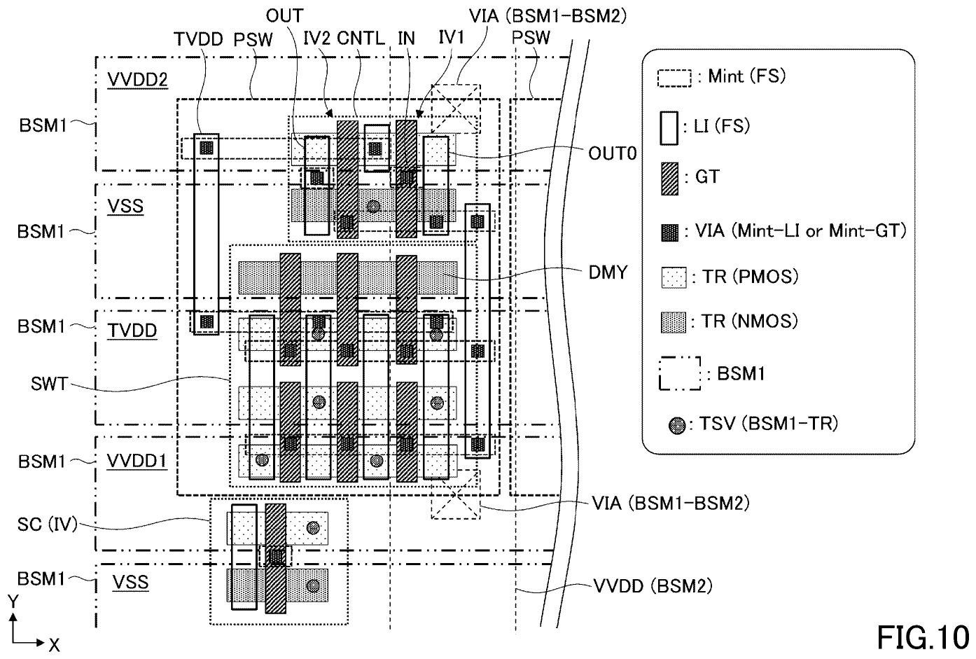

FIG. 10 illustrates a first modified example of the layout in the power switch circuit PSW illustrated in FIG. 3. In FIG. 10, the switch transistor SWT and the control circuit CNTL are arranged side by side in the Y direction in a plan view. The switch transistor SWT is, similarly to the layout illustrated in FIG. 5, arranged at a position overlapping the power supply line TVDD and the virtual power supply line VVDD1 of the interconnect layer BSM1 in a plan view. The control circuit CNTL is arranged at a position overlapping the virtual power supply line VVDD2 and the ground line VSS of the interconnect layer BSM1 in a plan view. In other words, the control circuit CNTL is not arranged at a position overlapping the power supply line TVDD of the interconnect layer BSM1 in a plan view.

For this reason, the source of the PMOS transistor of the control circuit CNTL is electrically coupled to the source of the PMOS transistor of the switch transistor SWT via the local interconnect LI and the Mint interconnect. This allows the source of the PMOS transistor of the control circuit CNTL to be electrically coupled to the power supply line TVDD of the interconnect layer BSM1. In other words, the source of the PMOS transistor of the inverters IV1 and IV2 of the control circuit CNTL can be electrically coupled to the power supply line TVDD of the interconnect layer BSM1 without depending on the layout in the power supply line TVDD formed in the interconnect layer BSM1. As a result, the degree of freedom of the layout in the control circuit CNTL can be increased.

The source of the PMOS transistor of the control circuit CNTL and the source of the PMOS transistor of the power switch circuit PSW may be coupled using an interconnect layer above the Mint layer. Although the inverters IV1 and IV2 of the control circuit CNTL may be included in the power supply switch circuit PSW in the example illustrated in FIG. 10, the inverters IV1 and IV2 may be arranged separately from the power supply switch circuit PSW. In this case, the power switch circuit PSW and the control circuit CNTL may be designed as different cells. One control circuit CNTL may control a plurality of power switch circuits PSW.

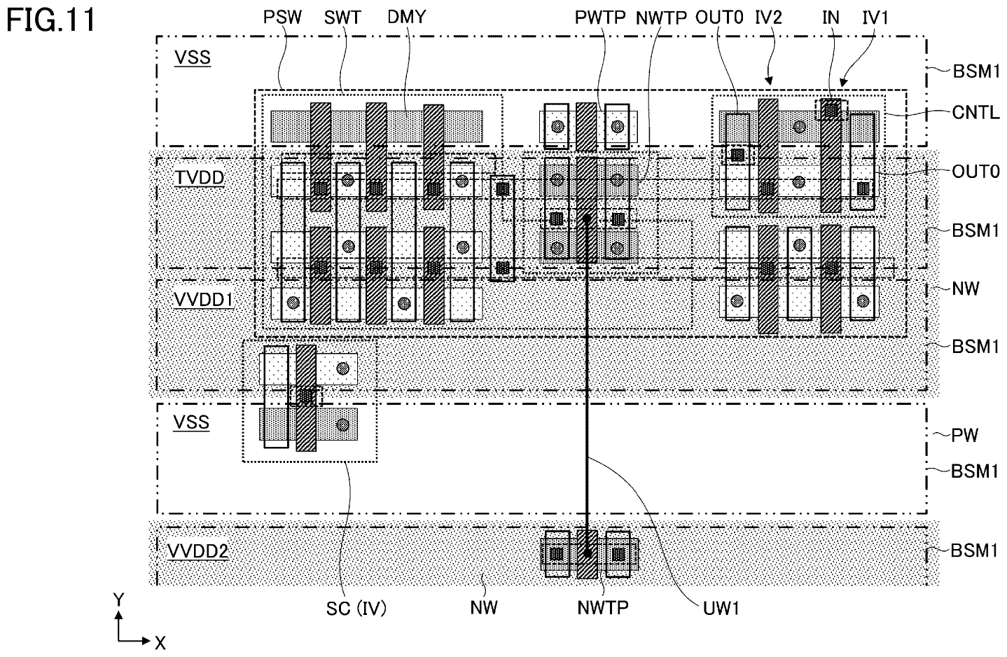

FIG. 11 illustrates a second modified example of the layout in the power switch circuit PSW illustrated in FIG. 3. The patterns indicating the elements in FIG. 11 are the same as those in FIGS. 5 and 10. The power supply switch circuit PSW illustrated in FIG. 11 is similar to the power supply switch circuit PSW in FIG. 5 except that the N-type well tap NWTP and the P-type well tap PWTP are arranged between the switch transistor SWT and the control circuit CNTL side by side in the Y direction. In other words, the switch transistor SWT and the control circuit CNTL are arranged in the X direction in a plan view.

The well tap NWTP is formed by an NMOS transistor whose gate is set to an open state. The well tap NWTP is arranged at a position overlapping the power supply line TVDD of the interconnect layer BSM1 in a plan view and a position overlapping the virtual power supply line VVDD2 of the interconnect layer BSM1 in a plan view.

The source and drain of the well tap NWTP overlapping the power supply line TVDD in a plan view are coupled to the power supply line TVDD of the interconnect layer BSM1 via the TSV. This makes it possible to supply the power supply potential TVDD to an N-type well region NW, which is the substrate region (shaded region) of the PMOS transistor. The TSVs directly coupled to the source and drain of the well tap NWTP are an example of a second via.

The well tap NWTP overlapping the virtual power supply line VVDD2 in a plan view is coupled to the source and drain of the well tap NWTP overlapping the power supply line TVDD, for example, using the LI interconnect, the Mint interconnect, and an interconnect UW1 of the interconnect layer above the Mint layer. Thus, the power supply potential TVDD can be supplied to the well tap NWTP and the well region NW indicated by hatching, which are not located at a position overlapping the power supply line TVDD in a plan view. The source or drain of the well tap NWTP overlapping the virtual power supply line VVDD2 may be electrically coupled to the source of the switch transistor SWT.

The well tap PWTP is formed by an PMOS transistor whose gate is set to an open state. The well tap PWTP is arranged at a position overlapping the ground line VSS of the interconnect layer BSM1 in a plan view. The well tap PWTP has a source and a drain coupled to the ground line VSS of the interconnect layer BSM1 via the TSV. This makes it possible to supply the ground potential VSS to a P-type well region PW, which is the substrate region (shaded region) of the NMOS transistor.

The well region NW is an N-type impurity region formed in the substrate SUB and is electrically coupled to the channel of the fin FET (PMOS). The well region PW is a P-type substrate SUB or a P-type impurity region formed in the substrate SUB and is electrically coupled to the channel of the fin FET (NMOS). In FIG. 11, the control circuit CNTL may be arranged at a position away from the power switch circuit PSW as a cell different from the power switch circuit PSW.

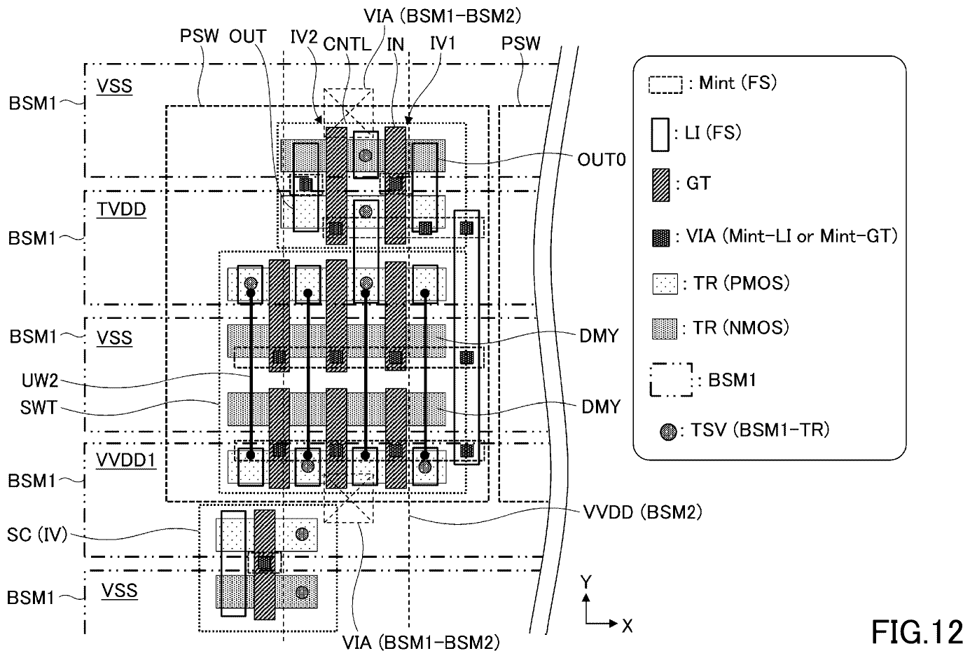

FIG. 12 illustrates a third modified example of the layout of the power switch circuit PSW illustrated in FIG. 3. In FIG. 12, the switch transistor SWT and the control circuit CNTL are arranged side by side in the Y direction in a plan view.

In FIG. 12, the switch transistor SWT is arranged at a position overlapping the power supply line TVDD and the virtual power supply line VVDD1 of the interconnect layer BSM1 in a plan view. The power switch circuit PSW is arranged at a position overlapping the ground line VSS adjacent to the power supply line TVDD in a plan view. The control circuit CNTL is arranged at a position overlapping the ground line VSS and the power supply line TVDD of the interconnect layer BSM1 in a plan view. In other words, the control circuit CNTL is not arranged at a position overlapping the power supply line TVDD of the interconnect layer BSM1 in a plan view. The control circuit CNTL may be arranged side by side with the switch transistor SWT in the X direction, as in FIG. 5.

In the switch transistor SWT, a PMOS transistor that couples the power supply line TVDD and the virtual power supply line VVDD1 may be formed. For this reason, in the switch transistor SWT, a dummy transistor DMY is arranged in a region overlapping the ground line VSS of the interconnect layer BSM1 in a plan view. The switch transistor SWT may be arranged, in place of the dummy transistor DMY, at a position overlapping the ground line VSS. In this case, the switch transistor SWT at a position overlapping the ground line VSS is arranged as a PMOS. The source and drain of the switch transistor SWT at a position overlapping the ground line VSS are coupled in common to the source and drain of the switch transistor SWT at a position overlapping the power supply line TVDD and the virtual power supply line VVDD.

The PMOS transistor formed on each Y-direction side of the dummy transistor DMY straddles the dummy transistor DMY, and thus cannot be coupled by the LI interconnect. Therefore, the source and drain of the PMOS transistor overlapping the virtual power supply line VVDD1 of the interconnect layer BSM1 in a plan view are coupled to the source and drain of the PMOS transistor overlapping the power supply line TVDD of the interconnect layer BSM1 in a plan view via an interconnect UW2 of the interconnect layer above the Mint layer, for example.

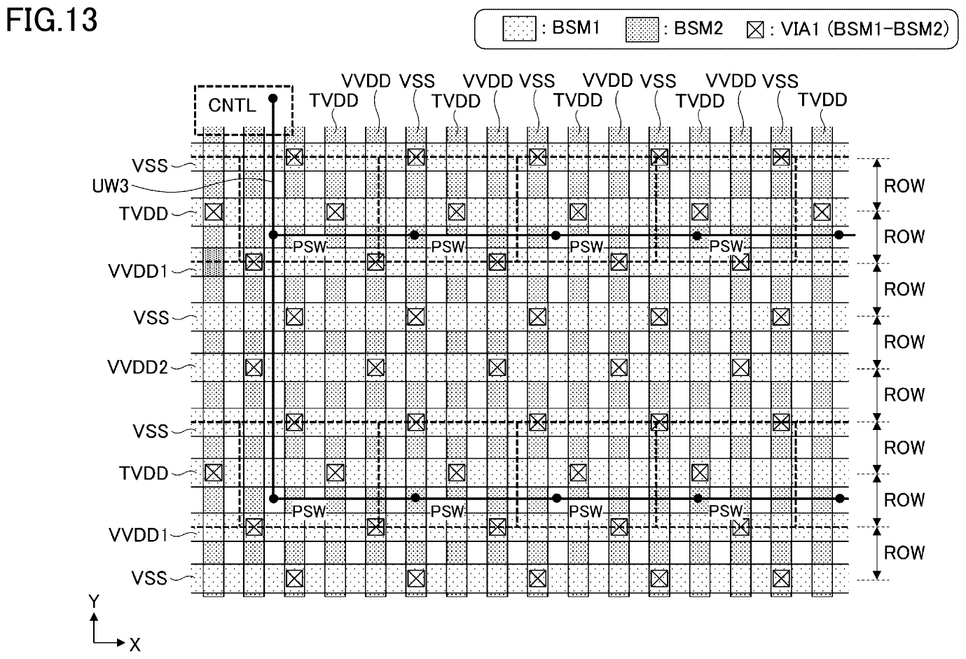

FIG. 13 illustrates a modified example of the layout illustrated in FIG. 4. In the example illustrated in FIG. 13, the control circuit CNTL is arranged separately from the power switch circuit PSW. An output signal OUT0 (FIG. 3) that is output from the control circuit CNTL is supplied in common to the plurality of power supply switch circuits PSW by using a signal line UW3 provided on the front surface side FS of the substrate SUB. In the layout illustrated in FIG. 13, the circuit area can be decreased as compared with the case where the control circuit CNTL is provided for each power switch circuit PSW.

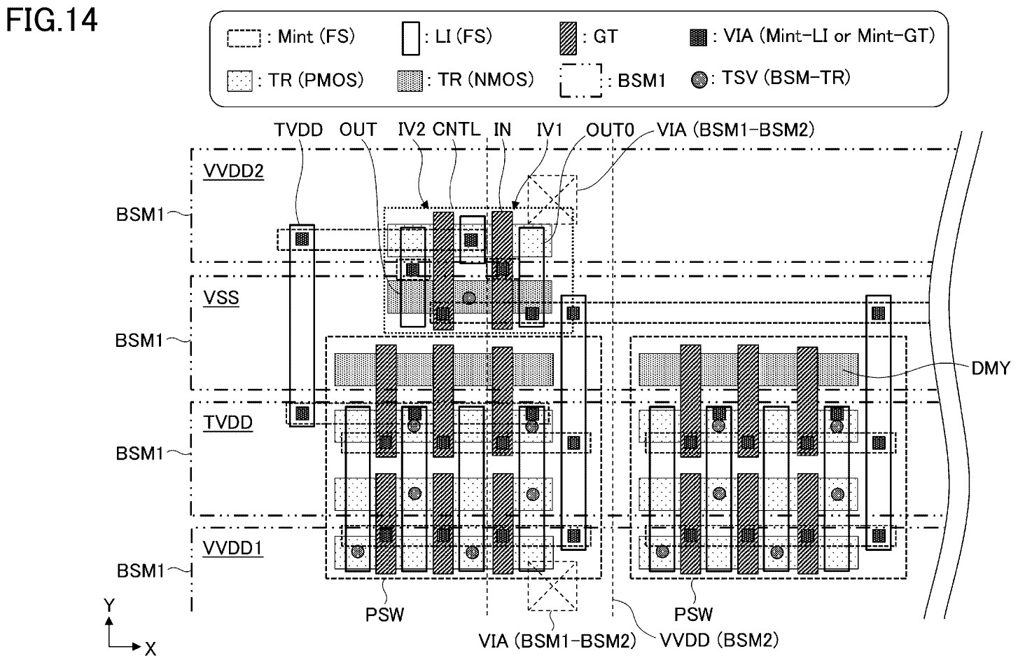

FIG. 14 illustrates an example of a layout in the power switch circuit and the control circuit illustrated in FIG. 13. In FIG. 14, the control circuit CNTL is arranged along the Y direction of the switch transistor SWT (not illustrated). An output signal OUT0 that is output from the inverter IV1 of the control circuit CNTL is supplied to the gates of the PMOS transistors of the plurality of power supply switch circuits PSW via the local interconnect LI and the Mint interconnect. The illustration of the interconnect for supplying an output signal OUT0 to the switch transistor SWT which is farther away from the control circuit CNTL in the Y direction than the switch transistor SWT illustrated in FIG. 14 is omitted.

Instead of the local interconnect LI for an output signal OUT0 formed between the inverter IV1 and the power supply switch circuit PSW, an interconnect in an interconnect layer above the Mint layer may be used. As in FIG. 11, the well taps NWTP and PWTP may be provided in each power supply switch circuit PSW. In this case, the well tap NWTP and the switch transistor SWT may be arranged side by side.

As described above, in this embodiment, by reducing the arrangement frequency of the power supply lines TVDD, the virtual power supply lines VVDD2 formed at positions not overlapping the power switching circuits PSW in a plan view can be coupled to the sources of the PMOS transistors of the power switching circuit PSW. In other words, in a layout in which the arrangement frequency of the power supply lines TVDD in the interconnect layer BSM1 is reduced, the virtual power potential VVDD can be supplied from the power switching circuit PSW to the virtual power supply line VVDD2 that is not formed at a position overlapping the power switching circuit PSW in a plan view.

By reducing the arrangement frequency of the power supply lines TVDD, the arrangement frequency of the virtual power supply lines VVDD and the ground lines VSS can be relatively increased, and the interconnect resistance of the virtual power supply lines VVDD and the ground lines VSS can be relatively decreased.

By supplying an output signal OUT0 from the control circuit CNTL in common to the plurality of power supply switch circuits PSW, the circuit area can be decreased as compared with the case where the control circuit CNTL is provided for each power supply switch circuit PSW, for example.

By coupling the well tap NWTP overlapping the power supply line TVDD in a plan view to the well tap NWTP overlapping the virtual power supply line VVDD2 in a plan view using an interconnect on the front surface side FS of the substrate SUB, the power potential TVDD can be supplied to the well region NW that is not located at a position overlapping the power supply line TVDD in a plan view.

Although the present invention has been described above based on the respective embodiments, the present invention is not limited to the requirements illustrated in the above embodiments. These embodiments can be changed within a range not departing from the gist of the present invention, and can be appropriately determined according to the application form.

What is claimed is:

1. A semiconductor device, comprising:
a substrate in which a first via is formed;
a first power supply line supplied with a first potential, a second power supply line supplied with a second potential, a third power supply line supplied with a third potential, a fourth power supply line supplied with the second potential, the first power supply line, the second power supply line, the third power supply line, and the fourth power supply line being formed below the substrate; and
a power switch circuit including a first transistor formed above the substrate and electrically coupled between the first power supply line and the second power supply line, wherein
the first power supply line, the second power supply line, the third power supply line, and the fourth power supply line each continuously extend in a first direction in a plan view,
the first transistor includes a first source and a first drain,
the first transistor is arranged at a position overlapping the first power supply line in a plan view,
the first source is coupled to the first via coupled to the first power supply line,
the first power supply line, the second power supply line, the third power supply line, and the fourth power supply line are arranged side by side in a second direction different from the first direction in a plan view,
the second power supply line and the fourth power supply line are electrically coupled to each other via an interconnect extending in the second direction, and
the power switch circuit is arranged at a position overlapping the second power supply line and not overlapping the fourth power supply line in a plan view.

2. The semiconductor device according to claim 1, wherein
the power switch circuit is provided in plurality and the plurality of power switch circuits are arranged along the first direction.

3. The semiconductor device according to claim 2, wherein
the first drain of the first transistor of each of the plurality of power switch circuits is electrically coupled to, via an interconnect extending in the second direction, the fourth power supply line not overlapping the power switch circuit in a plan view.

4. The semiconductor device according to claim 1, wherein
the power switch circuit further includes a control circuit configured to control a gate potential of the first transistor, and
the first transistor and the control circuit are arranged along the second direction.

5. The semiconductor device according to claim 4, wherein
the control circuit controls the gate potential of the first transistor of each of the plurality of power switch circuits.

6. The semiconductor device according to claim 1 further comprising:
a well tap arranged above the substrate and at a position overlapping the first power supply line in a plan view, coupled to a second via formed in the substrate, and configured to supply the first potential to a first well of the first transistor; and
an interconnect that electrically couples the first well of the first transistor and a second well of a transistor arranged at a position not overlapping the first power supply line in a plan view.

7. The semiconductor device according to claim 1, wherein
the power switch circuit is arranged at a position overlapping the third power supply line adjacent to the first power supply line in a plan view.
